(19) United States
(12) Patent Application Publication
(10) Pub. No.: US 2026/0078490 A1
(43) Pub. Date: Mar. 19, 2026

(54) SUSCEPTOR AND VAPOR PHASE GROWTH APPARATUS

(71) Applicants: Kabushiki Kaisha Toshiba, Tokyo (JP); Toshiba Electronic Devices & Storage Corporation, Tokyo (JP)

(72) Inventors: Masaharu SHIMABAYASHI, Ibo Hyogo (JP); Tsutomu KIYOSAWA, Himeji Hyogo (JP)

(21) Appl. No.: 19/048,162

(22) Filed: Feb. 7, 2025

(30) Foreign Application Priority Data
Sep. 18, 2024 (JP) 2024-160632

(51) Int. Cl. C23C 16/458; H01L 21/687

(52) U.S. Cl. CPC C23C 16/4583; H10P 72/7624

(57) ABSTRACT

A susceptor in a vapor phase growth apparatus and configured to allow a wafer to be mounted thereon. The susceptor has a support surface configured to support a downward facing surface of the wafer from below. The support surface has a susceptor engagement portion configured to be engaged with a wafer engagement portion of the wafer.

### CROSS-REFERENCE TO RELATED APPLICATION

This application is based upon and claims the benefit of priority from Japanese Patent Application No. 2024-160632, filed on Sep. 18, 2024, the entire contents of which are incorporated herein by reference.

### FIELD

Embodiments described herein relate generally to a susceptor and a vapor phase growth apparatus.

### BACKGROUND

Vapor phase growth apparatus, in which the uniformity of the thickness of a film is improved by depositing a SiC film or the like on a front surface of a wafer while a susceptor having the wafer mounted thereon is rotated, are known. In such vapor phase growth apparatus, in order to curb a situation in which the wafer falls off from the susceptor, a wafer guide having an upper surface located above the front surface of the wafer and surrounding the susceptor may be provided. In this case, since the flow rate of a material gas supplied to a radial outer edge on the front surface of the wafer will decrease, there is concern that the thickness of a film deposited in the radial outer edge of the wafer may become thin. Therefore, there is concern that the uniformity of the thickness of the film may deteriorate.

### BRIEF DESCRIPTION OF THE DRAWINGS

FIG. 1 is a cross-sectional view showing a vapor phase growth apparatus of a first embodiment.

FIG. 2 is a cross-sectional view showing a part of the vapor phase growth apparatus of the first embodiment.

FIG. 3 is a plan view of a susceptor of the first embodiment viewed from above.

FIG. 4 is a first cross-sectional view showing a step of manufacturing a wafer of the first embodiment.

FIG. 5 is a second cross-sectional view showing another step of manufacturing a wafer of the first embodiment.

FIG. 6 is a third cross-sectional view showing another step of manufacturing a wafer of the first embodiment.

FIG. 7 is a cross-sectional view showing a part of a vapor phase growth apparatus of a comparative example.

FIG. 8 is a cross-sectional view showing a part of a vapor phase growth apparatus of a second embodiment.

FIG. 9 is a cross-sectional view showing a part of a vapor phase growth apparatus of a third embodiment.

FIG. 10 is a cross-sectional view showing a part of a vapor phase growth apparatus of a fourth embodiment.

FIG. 11 is a cross-sectional view showing a part of a vapor phase growth apparatus of a fifth embodiment.

FIG. 12 is a plan view of a susceptor of a fifth embodiment viewed from above.

FIG. 13 is a cross-sectional view showing a part of a vapor phase growth apparatus of a sixth embodiment.

FIG. 14 is a plan view of a susceptor of the sixth embodiment viewed from above.

### DETAILED DESCRIPTION

A susceptor according to embodiments is a susceptor in a vapor phase growth apparatus and configured to allow a wafer to be mounted thereon. The susceptor has a support surface configured to support a downward facing surface of the wafer from below. The support surface has a susceptor engagement portion configured to be engaged with a wafer engagement portion of the wafer.

A vapor phase growth apparatus according to another embodiment has the susceptor, and a drive unit configured to rotate the susceptor.

Hereinafter, the susceptor and the vapor phase growth apparatus of the embodiment will be described with reference to the drawings.

In each of the drawings, a Z axis direction is a vertical direction. The side which the arrow in the Z axis direction faces (positive Z side) is an upward side in the vertical direction. The side opposite to the side which the arrow in the Z axis direction faces (negative Z side) is a downward side in the vertical direction. In the following description, the upward side in the vertical direction will be simply referred to as “an upward side”, and the downward side in the vertical direction will be simply referred to as “a downward side”. In the following description, an upward facing surface of an outer surface of each portion constituting the vapor phase growth apparatus may be referred to as a front surface, and a downward facing surface thereof may be referred to as a rear surface.

The direction, shown in each drawings, in which a rotation axis J extends is parallel to the Z axis direction. The rotation axis J is a virtual axis. In the vapor phase growth apparatus of the present embodiment, the susceptor rotates about the rotation axis J. In the following description, a radial direction about the rotation axis J will be simply referred to as “a radial direction”, and a circumferential direction about the rotation axis J will be simply referred to as “a circumferential direction”. In each drawings, the circumferential direction is indicated by the arrow θ.

In this specification, the terms such as “orthogonal”, “parallel”, “same”, and “similar”, the values of lengths and angles, and the like specifying the shape of each part constituting the vapor phase growth apparatus and the degree of the relative disposition relationship between parts will not be bound by their strict meanings and will be interpreted to include the range to the extent that similar functions can be expected and the range of design tolerances. In addition, each of the drawings is schematic and conceptual. The dimensions of each part constituting the vapor phase growth apparatus, the dimensional ratios between the parts, and the like are not necessarily the same as those in reality. Moreover, even when the same part is expressed, the dimensions and the ratios may be expressed differently from each other in each of the drawings.

### First Embodiment

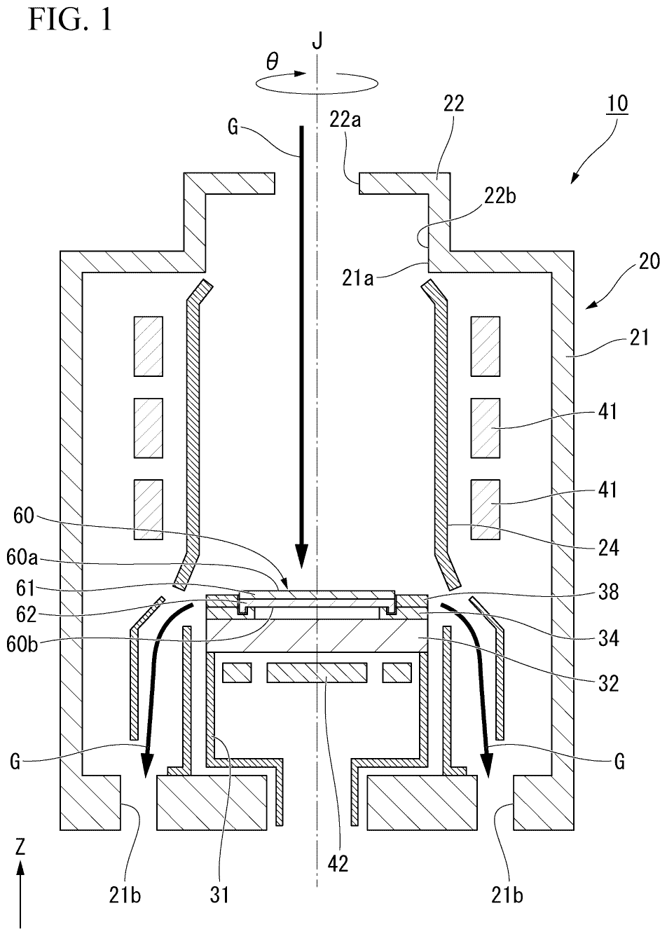

A vapor phase growth apparatus 10 of the present embodiment shown in FIG. 1 is a deposition apparatus for depositing an epitaxial film on a front surface 60a, that is, an upward facing surface of a wafer 60 by a chemical vapor deposition (CVD) method. In the present embodiment, a silicon carbide (SiC) film is deposited on the front surface 60a of the wafer 60. The film deposited on the front surface 60a of the wafer 60 may be a film constituted of a different material such as Si. The vapor phase growth apparatus 10 includes a chamber 20, a supply tube 24, a drive unit 31, a susceptor holding portion 32, a susceptor 34, a cover member 38, first heating portions 41, and a second heating portion 42.

The chamber 20 internally accommodates the supply tube 24, the drive unit 31, the susceptor holding portion 32, the susceptor 34, the cover member 38, the first heating portions 41, and the second heating portion 42. The chamber 20 has a main body portion 21 and a supply portion 22. In the present embodiment, the chamber 20 is made of metal.

The main body portion 21 internally accommodates the supply tube 24, the drive unit 31, the susceptor holding portion 32, the susceptor 34, the cover member 38, the first heating portions 41, and the second heating portion 42. The main body portion 21 has a tubular shape extending in the vertical direction. The main body portion 21 is provided with a main body portion opening 21a opening upward. The main body portion 21 is provided with a discharge port 21b opening downward. An excess material gas G inside the chamber 20 is discharged to the outside of the vapor phase growth apparatus 10 through the discharge port 21b.

The supply portion 22 has a tubular shape protruding upward from the main body portion 21. The supply portion 22 is provided with a supply port 22a opening upward. The supply portion 22 is provided with a supply portion opening 22b opening downward. The inside of the supply portion 22 and the inside of the main body portion 21 are connected to each other via the supply portion opening 22b and the main body portion opening 21a. The material gas G supplied to the inside of the supply portion 22 through the supply port 22a is supplied to the inside of the main body portion 21 via the supply portion opening 22b and the main body portion opening 21a.

The supply tube 24 is accommodated inside the main body portion 21. The supply tube 24 has a tubular shape extending in the vertical direction. The supply tube 24 opens to both the upward side and the downward side. At the time of deposition, the material gas G flows downward inside the supply tube 24. At the time of deposition, the material gas G flowing downward inside the supply tube 24 is supplied to the front surface 60a of the wafer 60. The excess material gas G inside the supply tube 24 is discharged to the outside of the vapor phase growth apparatus 10 via the downward opening of the supply tube 24 and the discharge port 21b. In the present embodiment, the supply tube 24 is made of graphite. A coating layer formed of materials such as SiC and tantalum carbide (TaC) may be provided on an inner surface of the supply tube 24.

In the present embodiment, the material gas G contains raw material gas, impurity gas, carrier gas, and hydrogen chloride (HCl) gas. The raw material gas contains silane (SiH₄) and propane (C₃H₈). The flow amount of the raw material gas is preferably in a range of several tens of [sccm] to several hundreds of [sccm]. The impurity gas contains nitrogen and trimethylaluminum (TMA). The flow amount of the impurity gas is preferably in a range of several [sccm] to several hundreds of [sccm]. The carrier gas is either argon gas or hydrogen gas. More specifically, the carrier gas used when the wafer 60 is carried into the vapor phase growth apparatus 10 and mounted on the susceptor 34 and when the wafer 60 after deposition is taken out from the susceptor 34 and carried out to the outside of the vapor phase growth apparatus 10 is argon gas. In addition, the carrier gas at the time of deposition is hydrogen gas. The flow amount of the carrier gas is preferably in a range of 100 [slm] to 200 [slm]. The flow amount of hydrogen chloride gas is preferably in a range of several tens of [sccm] to several [slm]. The flow amount and the like of each of the raw material gas, the impurity gas, the carrier gas, and the hydrogen chloride gas are adjusted by a gas adjustment portion (not shown).

The first heating portions 41 have a ring shape surrounding the supply tube 24. The first heating portions 41 are disposed between the main body portion 21 and the supply tube 24. In the present embodiment, the vapor phase growth apparatus 10 includes three first heating portions 41. The first heating portions 41 are disposed with a gap therebetween in the vertical direction. Each of the first heating portions 41 heats the material gas G passing through the inside of the supply tube 24. Accordingly, the temperature of the material gas G when it arrives at the wafer 60 can be increased, and therefore the deposition rate of a SiC film can be increased. In addition, each of silane and propane contained in the material gas G is subjected to pyrolysis into silylene (SiH₂) and methane (CH₄). The number of first heating portions 41 provided in the vapor phase growth apparatus 10 may be two or less or may be four or more.

The second heating portion 42 is disposed inside the drive unit 31. The second heating portion 42 is disposed below the susceptor holding portion 32. At the time of deposition, the second heating portion 42 heats each of the susceptor holding portion 32, the susceptor 34, and the wafer 60. At the time of deposition, the second heating portion 42 heats the wafer 60 to a temperature of 1,500° C. to 1,650° C. If the material gas G is supplied to the front surface 60a of the wafer 60 which has been heated to such a temperature, the SiC film is deposited on the front surface 60a of the wafer 60.

The drive unit 31 includes a drive device such as a motor (not shown), for example. The drive unit 31 is rotated around the rotation axis J by the drive device. The drive unit 31 is supported by a bottom portion of the main body portion 21 such that it can rotate around the rotation axis J. The drive unit 31 is disposed below the susceptor holding portion 32. The drive unit 31 rotates each of the susceptor holding portion 32, the susceptor 34, the cover member 38, and the wafer 60 around the rotation axis J. Accordingly, in the vapor phase growth apparatus 10 of the present embodiment, at the time of deposition of depositing the SiC film on the front surface 60a of the wafer 60, the wafer 60 can be rotated around the rotation axis J by the drive unit 31. For this reason, a variation in supply amount of the material gas G on the front surface 60a of the wafer 60 can be reduced. Therefore, the uniformity of the thickness of the film deposited on the front surface 60a of the wafer 60 can be improved.

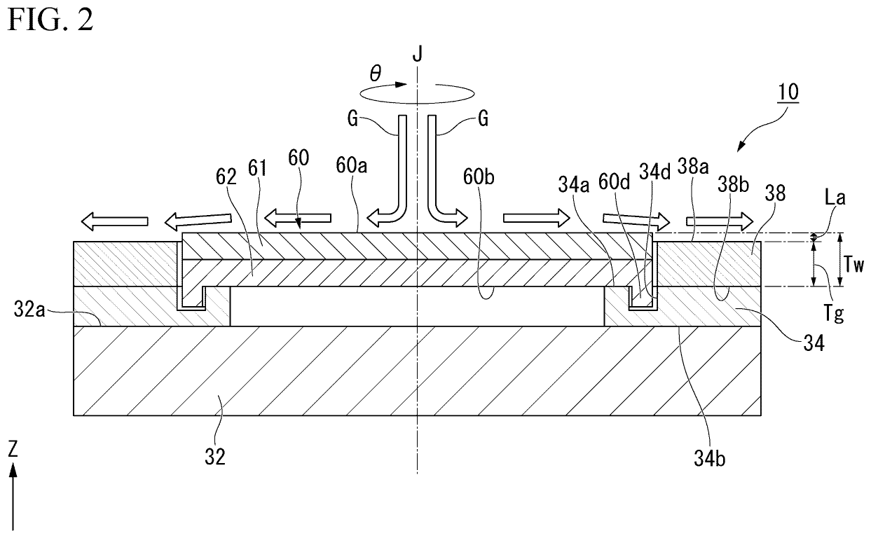

The susceptor holding portion 32 has a plate shape extending in a direction orthogonal to the vertical direction. In the present embodiment, the susceptor holding portion 32 substantially has a disk shape about the rotation axis J. When viewed in the vertical direction, the susceptor holding portion 32 may have a different shape such as an elliptical shape. As shown in FIG. 2, the susceptor 34 is fixed to a front surface 32a of the susceptor holding portion 32. Accordingly, the susceptor holding portion 32 holds the susceptor 34. In the present embodiment, the susceptor holding portion 32 is made of graphite. At least a part on the outer surface of the susceptor holding portion 32 may be provided with a coating layer formed of a material such as SiC and TaC.

The wafer 60 is mounted on the susceptor 34. The susceptor 34 supports the wafer 60 from below. In addition, the susceptor 34 supports the cover member 38 from below. In the present embodiment, the susceptor 34 has substantially a toric shape about the rotation axis J. The susceptor 34 is disposed above the susceptor holding portion 32. A rear surface 34b of the susceptor 34 is fixed to the front surface 32a of the susceptor holding portion 32. The outer diameter of the susceptor 34 and the outer diameter of the susceptor holding portion 32 are substantially the same dimensions. In the present embodiment, the susceptor 34 is made of graphite. The outer surface of the susceptor 34 may be provided with a coating layer formed of a material such as SiC and TaC. The susceptor 34 has a support surface 34a.

The support surface 34a is the upward facing surface of the outer surface of the susceptor 34. At the time of deposition, the wafer 60 is mounted on the support surface 34a. More specifically, at the time of deposition, the support surface 34a supports a rear surface 60b of the wafer 60, that is, the downward facing surface from below. Accordingly, at the time of deposition, the wafer 60 is mounted on the susceptor 34. The support surface 34a is provided with a susceptor engagement portion 34d.

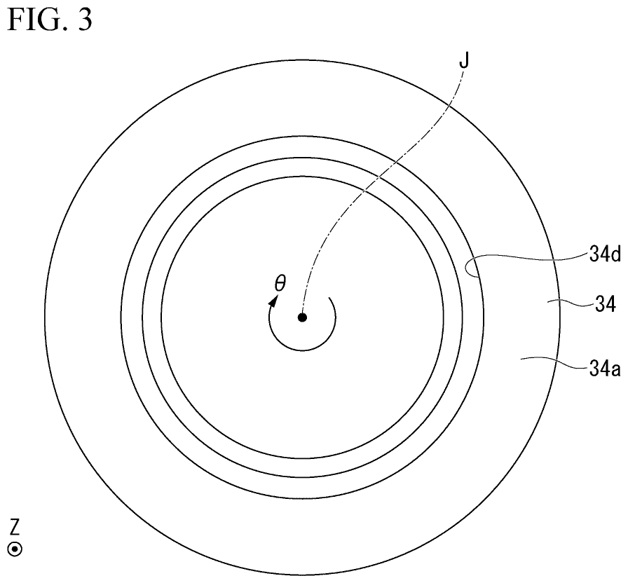

In the present embodiment, the susceptor engagement portion 34d is a depression depressed downward from the support surface 34a. As shown in FIG. 3, the susceptor engagement portion 34d has a toric shape about the rotation axis J in plan view. Namely, in the present embodiment, the susceptor engagement portion 34d is a groove extending throughout the circumference in the circumferential direction. As shown in FIG. 2, at the time of deposition, a wafer engagement portion 60d provided in the wafer 60 (which will be described below) is accommodated the susceptor engagement portion 34d. Each of a radially inward facing surface and a radially outward facing surface of the susceptor engagement portion 34d faces the wafer engagement portion 60d with a slight gap therebetween. Accordingly, the wafer engagement portion 60d is engaged with the susceptor engagement portion 34d. Each of the radially inward facing surface and the radially outward facing surface of the susceptor engagement portion 34d may come into contact with the wafer engagement portion 60d.

The cover member 38 has a ring shape surrounding the rotation axis J. In the present embodiment, the cover member 38 has substantially a toric shape about the rotation axis J. The cover member 38 is disposed above the susceptor 34. The inner diameter of the cover member 38 is larger than the inner diameter of the susceptor 34. In the radial direction, the position of the inner circumferential surface of the cover member 38 is substantially the same as the position of radially inward facing surface of the susceptor engagement portion 34d. A rear surface 38b of the cover member 38 is fixed to a part on the support surface 34a radially outward from the susceptor engagement portion 34d. Accordingly, the cover member 38 is attached to the susceptor 34. For this reason, the cover member 38 can rotate around the rotation axis J together with the susceptor 34. The outer diameter of the cover member 38 has substantially the same dimension as the outer diameter of the susceptor 34. At the time of deposition, the cover member 38 surrounds the outer edge of the wafer 60 mounted on the susceptor 34 from the radially outward side. The inner diameter of the cover member 38 is slightly larger than the outer diameter of the wafer 60. A thickness Tg of the cover member 38 shown in FIG. 2 is a dimension of the cover member 38 in the vertical direction. In the present embodiment, the cover member 38 is made of poly-SiC. The cover member 38 may be made of graphite. In this case, at least a part on a surface of the cover member 38 may be provided with a coating layer constituted using SiC. The vapor phase growth apparatus 10 may not include the cover member 38.

The wafer 60 substantially has a disk shape extending in a direction orthogonal to the vertical direction. At the time of deposition, the wafer 60 is mounted on a radially inward part on the support surface 34a of the susceptor 34. The rear surface 60b of the wafer 60 comes into contact with the support surface 34a in the vertical direction. In the present embodiment, a thickness Tw of the wafer 60 is 0.35 mm. The thickness Tw of the wafer 60 is a dimension of the wafer 60 in the vertical direction. The thickness Tw of the wafer 60 may be thinner than 0.35 mm or may be thicker than 0.35 mm. In the present embodiment, the wafer 60 has a first wafer 61, a second wafer 62, and the wafer engagement portion 60d.

The first wafer 61 is an upward part of the wafer 60. The first wafer 61 substantially has a disk shape extending in a direction orthogonal to the vertical direction. The upward facing surface of the first wafer 61 is the front surface 60a of the wafer 60. The SiC film or the like is formed on the front surface 60a of the wafer 60. In the present embodiment, the first wafer 61 is constituted using single crystal SiC.

The second wafer 62 is a downward part of the wafer 60. The second wafer 62 substantially has a disk shape extending in a direction orthogonal to the vertical direction. The outer diameter of the second wafer 62 has substantially the same dimension as the outer diameter of the first wafer 61. The downward facing surface of the second wafer 62 is the rear surface 60b of the wafer 60. In the present embodiment, the second wafer 62 is constituted using polycrystal SiC. The polycrystal SiC constituting the second wafer 62 is less expensive than the single crystal SiC constituting the first wafer 61 in terms of material cost. For this reason, in the present embodiment, compared to when the second wafer 62 is constituted using single crystal SiC, increase in cost of the wafer 60 can be curbed. The second wafer 62 may be constituted using single crystal SiC. In this case, the first wafer 61 and the second wafer 62 may be integrally molded.

The wafer engagement portion 60d is a projection protruding downward from the rear surface 60b. In the present embodiment, the wafer engagement portion 60d is a part of the second wafer 62. In the present embodiment, the wafer engagement portion 60d has a toric shape about the rotation axis J in plan view. Namely, in the present embodiment, the wafer engagement portion 60d is a projection extending throughout the circumference in the circumferential direction. In the present embodiment, the wafer engagement portion 60d extends throughout the circumference in the circumferential direction along the radial outer edge of the wafer 60. At the time of deposition, the wafer engagement portion 60d is accommodated inside the susceptor engagement portion 34d. Accordingly, the wafer engagement portion 60d is engaged with the susceptor engagement portion 34d.

At the time of deposition, if the susceptor 34 having the wafer 60 mounted thereon is rotated around the rotation axis J by the drive unit 31, a centrifugal force directed radially outward is applied to the wafer 60. For this reason, when the susceptor 34 does not have the susceptor engagement portion 34d and the wafer 60 does not have the wafer engagement portion 60d, there is concern that the wafer 60 may fall off from the susceptor 34 due to such a centrifugal force. In contrast, in the present embodiment, as described above, at the time of deposition, the wafer engagement portion 60d is engaged with the susceptor engagement portion 34d. For this reason, at the time of deposition, if a centrifugal force directed radially outward is applied to the wafer 60 and the wafer 60 tends to move radially outward with respect to the susceptor 34, the wafer engagement portion 60d is caught by at least one of the radially outward facing surface and the radially inward facing surface of the susceptor engagement portion 34d. Accordingly, a situation in which the wafer 60 moves radially outward with respect to the susceptor 34 can be curbed. Therefore, a situation in which the wafer 60 falls off from the susceptor 34 due to such a centrifugal force can be curbed.

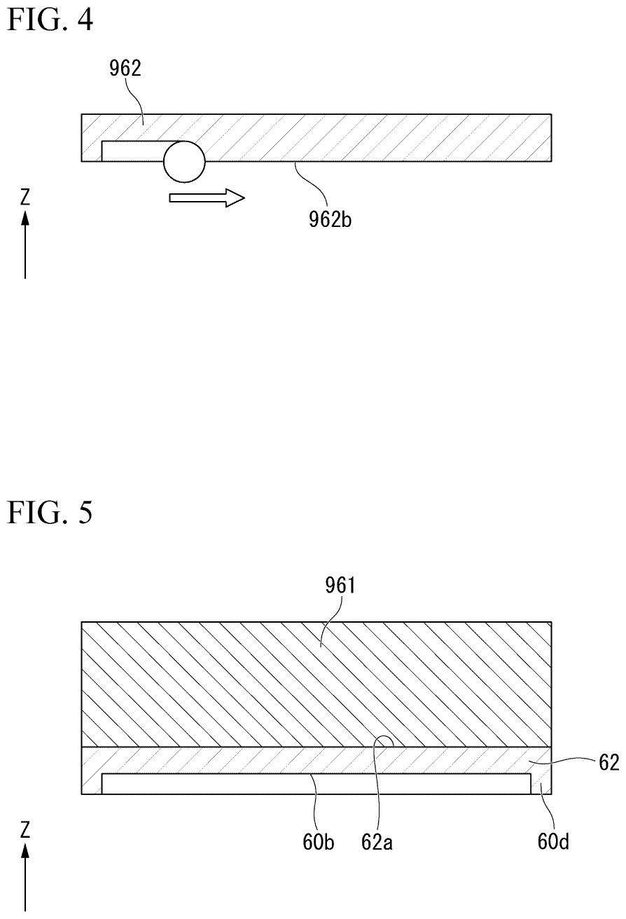

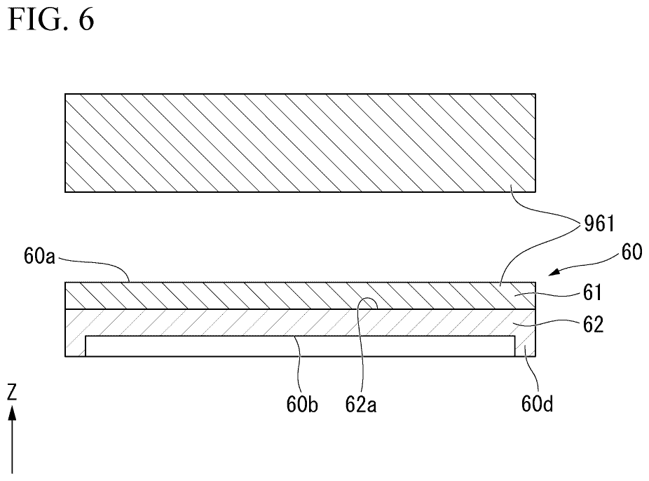

Next, a step of manufacturing the wafer 60 of the present embodiment will be described. First, as shown in FIG. 4, a radially inward part on a disk-shaped rear surface 962b of a second member 962 constituted using polycrystal SiC is polished. Accordingly, as shown in FIG. 5, the second wafer 62 having the wafer engagement portion 60d and the rear surface 60b is formed. Next, a surface 62a of the second wafer 62 is polished. Accordingly, impurities which have adhered to the surface 62a can be removed, and the smooth surface 62a can be obtained. Next, a disk-shaped first member 961 constituted using single crystal SiC is bonded to the surface 62a of the second wafer 62 at room temperature. Next, as shown in FIG. 6, the upward part of the first member 961 is removed by thermal peeling. Accordingly, the first wafer 61 bonded to the second wafer 62 is formed. Next, after the front surface 60a which is the upward facing surface of the first wafer 61 is activated, the front surface 60a is polished, and the wafer 60 is then manufactured.

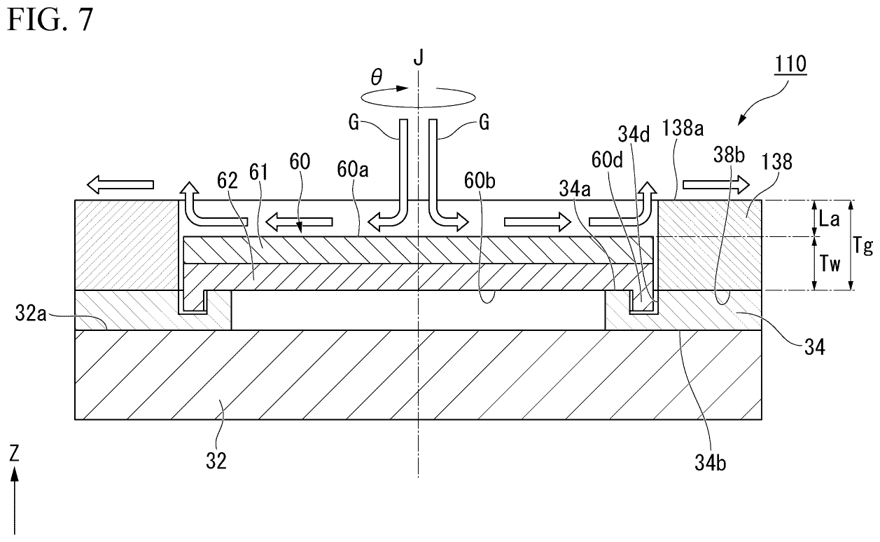

A protrusion height La shown in FIG. 2 is a distance between a front surface 38a of the cover member 38 and the front surface 60a of the wafer 60 in the vertical direction. As described above, in the present embodiment, each of the cover member 38 and the wafer 60 is supported by the susceptor 34 from below. Therefore, in the present embodiment, the protrusion height La is a difference between the thickness Tg of the cover member 38 and the thickness Tw of the wafer 60. In the present embodiment, as shown in FIG. 2, when the thickness Tg of the cover member 38 is smaller than the thickness Tw of the wafer 60, that is, when the front surface 38a of the cover member 38 is located below the front surface 60a of the wafer 60, the protrusion height La has a negative value. Although illustration is omitted, when the thickness Tg of the cover member 38 and the thickness Tw of the wafer 60 are the same thickness, the protrusion height La is 0 mm. In the present embodiment, as in a vapor phase growth apparatus 110 of a comparative example shown in FIG. 7, when the thickness Tg of a cover member 138 is larger than the thickness Tw of the wafer 60, that is, when a front surface 138a of the cover member 138 is located above the front surface 60a of the wafer 60, the protrusion height La has a positive value. In the present embodiment, the protrusion height La is 0.65 mm or smaller. That is, in the present embodiment, the front surface 38a of the cover member 38, that is, the upward facing surface is located below the level which is located 0.65 mm above the front surface 60a of the wafer 60, that is, the upward facing surface. In the present embodiment, the thickness Tg of the cover member 38 is smaller than 1.00 mm.

The thickness Tg of the cover member 138 included in the vapor phase growth apparatus 110 of the comparative example shown in FIG. 7 is 1.85 mm, for example. Therefore, in the vapor phase growth apparatus 110 of the comparative example, the protrusion height La is 1.50 mm, for example. In the vapor phase growth apparatus 110 of the comparative example, the front surface 138a of the cover member 138 is located above the level which is located 0.65 mm above the front surface 60a of the wafer 60. As described above, at the time of deposition of depositing the SiC film on the front surface 60a of the wafer 60, the material gas G flowing downward inside the supply tube 24 shown in FIG. 1 is supplied to the front surface 60a of the wafer 60. In addition, as described above, at the time of deposition, if the material gas G is supplied to the front surface 60a of the wafer 60 heated by the second heating portion 42, the SiC film is deposited on the front surface 60a of the wafer 60.

As shown in FIG. 7, at the time of deposition, the material gas G supplied to the front surface 60a of the wafer 60 flows radially outward along the front surface 60a of the wafer 60. Accordingly, the material gas G can be supplied to the entire front surface 60a of the wafer 60. However, when the protrusion height La is excessively large as in the vapor phase growth apparatus 110 of the comparative example, a flow of the material gas G flowing radially outward beyond the wafer 60 from the radial outer edge of the wafer 60 is hindered noticeably by the cover member 138. Accordingly, since the flow rate of the material gas G in the radial outer edge of the wafer 60 decreases significantly, the deposition rate in the radial outer edge on the front surface 60a of the wafer 60 decreases significantly. Therefore, since the thickness of the film deposited in the radial outer edge of the wafer 60 becomes excessively thinner than the thickness of the film deposited in a radially central portion of the wafer 60, it is difficult to improve the uniformity of the thickness of the film deposited on the front surface 60a of the wafer 60.

In contrast, as described above, in the present embodiment, the protrusion height La is smaller than 0.65 mm. For this reason, excessive increase in protrusion height La can be curbed. Therefore, as shown in FIG. 2, in the present embodiment, a hindrance to a flow of the material gas G flowing radially outward beyond the wafer 60 from the radial outer edge of the wafer 60 can be curbed by the cover member 38. Accordingly, since decrease in flow rate of the material gas G in the radial outer edge of the wafer 60 can be curbed, decrease in deposition rate in the radial outer edge on the front surface 60a of the wafer 60 can be curbed. Therefore, since a situation in which the thickness of the film deposited in the radial outer edge of the wafer 60 becomes excessively thinner than the thickness of the film deposited in the radially central portion of the wafer 60 can be curbed, the uniformity of the thickness of the film deposited on the front surface 60a of the wafer 60 can be improved.

According to the present embodiment, the susceptor 34 is the susceptor 34 in the vapor phase growth apparatus 10 and configured to allow the wafer 60 to be mounted thereon. The susceptor 34 has the support surface 34a configured to support the rear surface 60b of the wafer 60, that is, the downward facing surface from below. The support surface 34a has the susceptor engagement portion 34d configured to be engaged with the wafer engagement portion 60d of the wafer 60. Thus, since the wafer engagement portion 60d is engaged with the susceptor engagement portion 34d, as described above, at the time of deposition, a situation in which the wafer 60 falls off from the susceptor 34 can be curbed. Accordingly, in the present embodiment, there is no need to curb a situation in which the wafer 60 falls off from the susceptor 34 using the cover member 38. Therefore, in the present embodiment, the thickness Tg of the cover member 38 can be suitably set to a height at which decrease in flow rate of the material gas G in the radial outer edge of the wafer 60 can be curbed. Accordingly, decrease in deposition rate in the radial outer edge on the front surface 60a of the wafer 60 can be curbed. For this reason, as described above, a situation in which the thickness of the film deposited in the radial outer edge of the wafer 60 becomes excessively thinner than the thickness of the film deposited in the radially central portion of the wafer 60 can be curbed. Therefore, the uniformity of the thickness of the film deposited on the front surface 60a of the wafer 60 can be improved.

In addition, in the present embodiment, as described above, since a situation in which the wafer 60 falls off from the susceptor 34 can be curbed by engaging the wafer engagement portion 60d with the susceptor engagement portion 34d, the cover member 38 may not be provided. Therefore, in the present embodiment, with a constitution not including the cover member 38, the number of components and manufacturing costs of the vapor phase growth apparatus 10 can be reduced.

According to the present embodiment, the susceptor engagement portion 34d is a depression depressed downward from the support surface 34a and accommodating the wafer engagement portion 60d. Thus, when the susceptor 34 having the wafer 60 mounted thereon is rotated, if the wafer 60 tends to move radially outward with respect to the susceptor 34, as described above, the wafer engagement portion 60d is caught by at least one of the radially outward facing surface and the radially inward facing surface of the susceptor engagement portion 34d. Accordingly, a situation in which the wafer 60 moves radially outward with respect to the susceptor 34 can be favorably curbed. Therefore, a situation in which the wafer 60 falls off from the susceptor 34 can be favorably curbed.

In the present embodiment, as described above, the susceptor engagement portion 34d is a depression depressed downward from the support surface 34a. Therefore, a situation in which the wafer 60 falls off from the susceptor 34 can be curbed with a simple constitution without using another member for curbing a situation in which the wafer 60 falls off from the susceptor 34. Therefore, an increase in the number of components and manufacturing costs of the vapor phase growth apparatus 10 can be more favorably curbed.

According to the present embodiment, the susceptor engagement portion 34d has a toric shape in plan view. Thus, when the susceptor 34 having the wafer 60 mounted thereon is rotated, even if the wafer 60 moves in the radial direction with respect to the susceptor 34, a part of at least one of the radially outward facing surface and the radially inward facing surface of the susceptor engagement portion 34d in the circumferential direction is reliably caught by the wafer engagement portion 60d. Accordingly, a situation in which the wafer 60 moves radially outward with respect to the susceptor 34 can be more favorably curbed. Therefore, a situation in which the wafer 60 falls off from the susceptor 34 can be more favorably curbed.

According to the present embodiment, the vapor phase growth apparatus 10 includes the susceptor 34, and the drive unit 31 configured to rotate the susceptor 34. Thus, at the time of deposition of depositing a film on the front surface 60a of the wafer 60, the wafer 60 can be rotated around the rotation axis J by the drive unit 31. For this reason, as described above, a variation in supply amount of the material gas G on the front surface 60a of the wafer 60 can be reduced. Therefore, the uniformity of the thickness of the film deposited on the front surface 60a of the wafer 60 can be improved.

According to the present embodiment, the vapor phase growth apparatus 10 includes the ring-shaped cover member 38 surrounding the wafer 60, and the front surface 38a of the cover member 38, that is, the upward facing surface is located below the level which is located 0.65 mm above the front surface 60a of the wafer 60, that is, the upward facing front surface 60a. For this reason, excessive increase in protrusion height La which is a distance between the front surface 38a of the cover member 38 and the front surface 60a of the wafer 60 in the vertical direction can be curbed. Accordingly, as described above, a hindrance to a flow of the material gas G flowing radially outward beyond the wafer 60 from the radial outer edge of the wafer 60 can be curbed by the cover member 38. For this reason, as described above, the difference between the deposition rate in the radial outer edge on the front surface 60a of the wafer 60 and the deposition rate in the radially central portion on the front surface 60a of the wafer 60 can be reduced. Therefore, the uniformity of the thickness of the film deposited on the front surface 60a of the wafer 60 can be improved.

### Second Embodiment

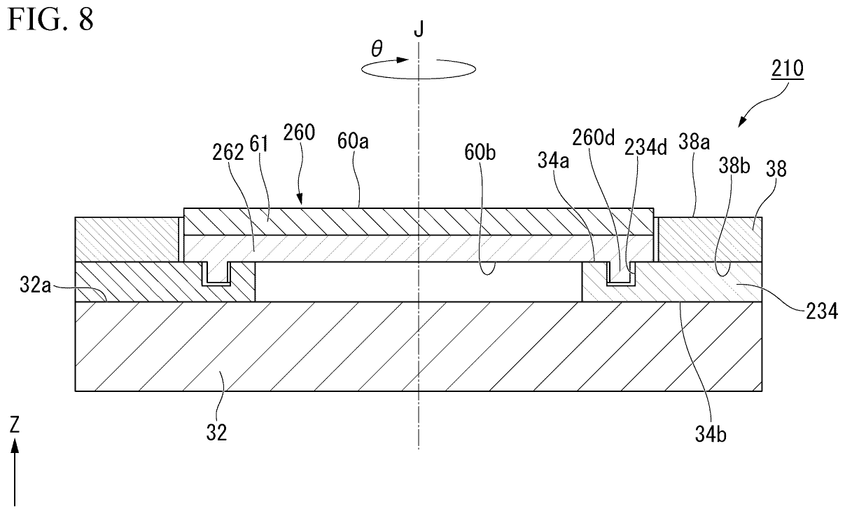

FIG. 8 is a cross-sectional view showing a part of a vapor phase growth apparatus 210 of the present embodiment. In the following description, the same reference signs are applied to constituent elements having the same forms as those in the embodiment described above, and a description thereof may be omitted.

A wafer 260 is mounted on a susceptor 234. The susceptor 234 supports each of the wafer 260 and the cover member 38 from below. The support surface 34a of the susceptor 234 supports the rear surface 60b of the wafer 260 from below. The support surface 34a is provided with a susceptor engagement portion 234d.

In the present embodiment, the susceptor engagement portion 234d is a depression depressed downward from the support surface 34a. The susceptor engagement portion 234d has a toric shape about the rotation axis J. in plan view. At the time of deposition, a wafer engagement portion 260d provided in the wafer 260 (which will be described below) is accommodated in the susceptor engagement portion 234d. Other constitutions and the like of the susceptor 234 of the present embodiment are similar to other constitutions and the like of the susceptor 34 of the first embodiment described above.

The wafer 260 substantially has a disk shape extending in a direction orthogonal to the vertical direction. At the time of deposition, the wafer 260 is mounted in a radially inward part on the support surface 34a of the susceptor 234. In the present embodiment, the wafer 260 has the first wafer 61, a second wafer 262, and the wafer engagement portion 260d.

The second wafer 262 substantially has a disk shape extending in a direction orthogonal to the vertical direction. The downward facing surface of the second wafer 262 is the rear surface 60b of the wafer 260. The wafer engagement portion 260d is a projection protruding downward from the rear surface 60b. In the present embodiment, the wafer engagement portion 260d is a part of the second wafer 262. In the present embodiment, the wafer engagement portion 260d has a toric shape about the rotation axis J in plan view. In the present embodiment, the wafer engagement portion 260d is provided radially inward from the radial outer edge of the wafer 260. At the time of deposition, the wafer engagement portion 260d is accommodated inside the susceptor engagement portion 234d. Each of the radially outward facing surface and the radially inward facing surface of the susceptor engagement portion 234d faces the wafer engagement portion 260d with a slight gap therebetween. Accordingly, the wafer engagement portion 260d is engaged with the susceptor engagement portion 234d. Each of the radially outward facing surface and the radially inward facing surface of the susceptor engagement portion 234d may come into contact with the wafer engagement portion 260d. Other constitutions and the like of the wafer 260 of the present embodiment are similar to other constitutions and the like of the wafer 60 of the first embodiment described above. Other constitutions and the like of the vapor phase growth apparatus 210 of the present embodiment are similar to other constitutions and the like of the vapor phase growth apparatus 10 of the first embodiment described above.

According to the present embodiment, the susceptor 234 has the support surface 34a configured to support the rear surface 60b of the wafer 260, that is, the downward facing surface from below, and the support surface 34a has the susceptor engagement portion 234d configured to be engaged with the wafer engagement portion 260d of the wafer 260. Thus, similar to the first embodiment described above, at the time of deposition, a situation in which the wafer 260 falls off from the susceptor 234 can be curbed. Therefore, the thickness Tg of the cover member 38 can be suitably set to a height at which decrease in flow rate of the material gas G in the radial outer edge of the wafer 260 can be curbed. For this reason, similar to the first embodiment described above, a situation in which the thickness of the film deposited in the radial outer edge of the wafer 260 becomes excessively thinner than the thickness of the film deposited in the radially central portion of the wafer 260 can be curbed. Therefore, the uniformity of the thickness of the film deposited on the front surface 60a of the wafer 260 can be improved.

### Third Embodiment

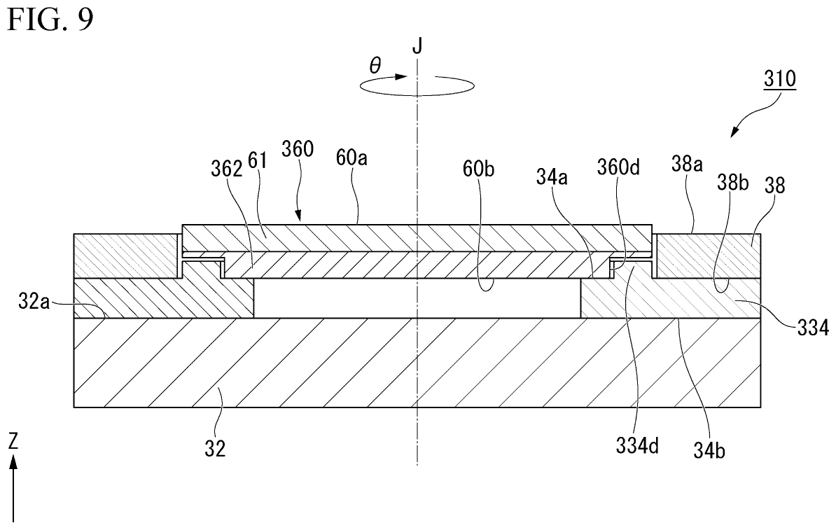

FIG. 9 is a cross-sectional view showing a part of a vapor phase growth apparatus 310 of the present embodiment. In the following a description, the same reference signs are applied to constituent elements having the same forms as those in the embodiments described above, and a description thereof may be omitted.

A wafer 360 is mounted on a susceptor 334. The susceptor 334 supports each of the wafer 360 and the cover member 38 from below. The support surface 34a of the susceptor 334 supports the rear surface 60b of the wafer 360 from below. The support surface 34a is provided with a susceptor engagement portion 334d.

In the present embodiment, the susceptor engagement portion 334d is a projection protruding upward from the support surface 34a. The susceptor engagement portion 334d has a toric shape about the rotation axis J in plan view. At the time of deposition, the susceptor engagement portion 334d is accommodated inside a wafer engagement portion 360d provided in the wafer 360 (which will be described below). Other constitutions and the like of the susceptor 334 of the present embodiment are similar to other constitutions and the like of the susceptor 34 of the first embodiment described above.

The wafer 360 substantially has a disk shape extending in a direction orthogonal to the vertical direction. At the time of deposition, the wafer 360 is mounted in a radially inward part on the support surface 34a of the susceptor 334. In the present embodiment, the wafer 360 has the first wafer 61, a second wafer 362, and the wafer engagement portion 360d.

The second wafer 362 substantially has a disk shape extending in a direction orthogonal to the vertical direction. The downward facing surface of the second wafer 362 is the rear surface 60b of the wafer 360. The wafer engagement portion 360d is a depression depressed upward from the rear surface 60b. In the present embodiment, the wafer engagement portion 360d opens radially outward. In the present embodiment, the wafer engagement portion 360d extends throughout the circumference in the circumferential direction along the radial outer edge of the wafer 360. At the time of deposition, the susceptor engagement portion 334d is accommodated inside the wafer engagement portion 360d. The susceptor engagement portion 334d faces the radially outward facing surface of the wafer engagement portion 360d with a slight gap therebetween. Accordingly, the susceptor engagement portion 334d is engaged with the wafer engagement portion 360d. Other constitutions and the like of the wafer 360 of the present embodiment are similar to other constitutions and the like of the wafer 60 of the first embodiment described above. Other constitutions and the like of the vapor phase growth apparatus 310 of the present embodiment are similar to other constitutions and the like of the vapor phase growth apparatus 10 of the first embodiment described above.

According to the present embodiment, the susceptor engagement portion 334d is a projection protruding upward from the support surface 34a and accommodated inside the wafer engagement portion 360d. Thus, when the susceptor 334 having the wafer 360 mounted thereon is rotated, if the wafer 360 tends to move radially outward with respect to the susceptor 334, the susceptor engagement portion 334d is caught by the radially outward facing surface of the wafer engagement portion 360d. Accordingly, a situation in which the wafer 360 moves radially outward with respect to the susceptor 334 can be favorably curbed. Therefore, a situation in which the wafer 360 falls off from the susceptor 334 can be favorably curbed.

In addition, in the present embodiment, as described above, since a situation in which the wafer 360 falls off from the susceptor 334 can be favorably curbed, similar to the first embodiment described above, the thickness Tg of the cover member 38 can be suitably set to a height at which decrease in flow rate of the material gas G in the radial outer edge of the wafer 360 can be curbed. For this reason, a situation in which the thickness of the film deposited in the radial outer edge of the wafer 360 becomes excessively thinner than the thickness of the film deposited in the radially central portion of the wafer 360 can be curbed. Therefore, the uniformity of the thickness of the film deposited on the front surface 60a of the wafer 360 can be improved.

### Fourth Embodiment

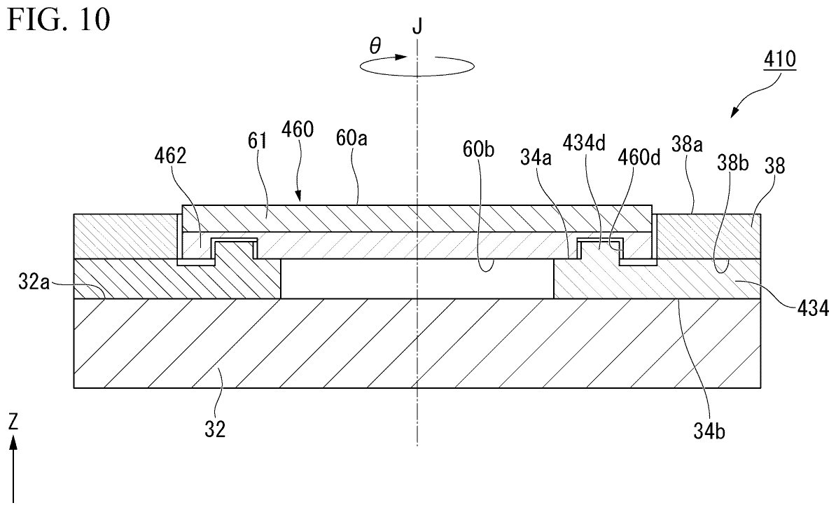

FIG. 10 is a cross-sectional view showing a part of a vapor phase growth apparatus 410 of the present embodiment. In the following description, the same reference signs are applied to constituent elements having the same forms as those in the embodiments described above, and a description thereof may be omitted.

A wafer 460 is mounted on a susceptor 434. The susceptor 434 supports each of the wafer 460 and the cover member 38 from below. The support surface 34a of the susceptor 434 supports the rear surface 60b of the wafer 460 from below. The support surface 34a is provided with a susceptor engagement portion 434d.

In the present embodiment, the susceptor engagement portion 434d is a projection protruding upward from the support surface 34a. The susceptor engagement portion 434d has a toric shape about the rotation axis J in plan view. At the time of deposition, the susceptor engagement portion 434d is accommodated inside a wafer engagement portion 460d provided in the wafer 460 (which will be described below). Other constitutions and the like of the susceptor 434 of the present embodiment are similar to other constitutions and the like of the susceptor 334 the third embodiment described above.

The wafer 460 substantially has a disk shape extending in a direction orthogonal to the vertical direction. At the time of deposition, the wafer 460 is mounted in a radially inward part on the support surface 34a of the susceptor 434. In the present embodiment, the wafer 460 has the first wafer 61, a second wafer 462, and the wafer engagement portion 460d.

The second wafer 462 substantially has a disk shape extending in a direction orthogonal to the vertical direction. The downward facing surface of the second wafer 462 is the rear surface 60b of the wafer 460. The wafer engagement portion 460d is a depression depressed upward from the rear surface 60b. In the present embodiment, the wafer engagement portion 460d has a toric shape about the rotation axis J in plan view. In the present embodiment, the wafer engagement portion 460d is provided radially inward from the radial outer edge of the wafer 460. At the time of deposition, the susceptor engagement portion 434d is accommodated inside the wafer engagement portion 460d. The susceptor engagement portion 434d faces each of the radially outward facing surface and the radially inward facing surface of the wafer engagement portion 460d with a slight gap therebetween. Accordingly, the susceptor engagement portion 434d is engaged with the wafer engagement portion 460d. The susceptor engagement portion 434d may come into contact with each of the radially outward facing surface and the radially inward facing surface of the wafer engagement portion 460d. Other constitutions and the like of the wafer 460 of the present embodiment are similar to other constitutions and the like of the wafer 360 of the third embodiment described above. Other constitutions and the like of the vapor phase growth apparatus 410 of the present embodiment are similar to other constitutions and the like of the vapor phase growth apparatus 310 of the third embodiment described above.

According to the present embodiment, the susceptor 434 has the support surface 34a configured to support the rear surface 60b of the wafer 460, that is, the downward facing surface from below, and the support surface 34a has the susceptor engagement portion 434d configured to be engaged with the wafer engagement portion 460d of the wafer 460. Thus, similar to the third embodiment described above, at the time of deposition, a situation in which the wafer 460 falls off from the susceptor 434 can be curbed. Therefore, the thickness Tg of the cover member 38 can be suitably set to a height at which decrease in flow rate of the material gas G in the radial outer edge of the wafer 460 can be curbed. For this reason, similar to the third embodiment described above, a situation in which the thickness of the film deposited in the radial outer edge of the wafer 460 becomes excessively thinner than the thickness of the film deposited in the radially central portion of the wafer 460 can be curbed. Therefore, the uniformity of the thickness of the film deposited on the front surface 60a of the wafer 460 can be improved.

### Fifth Embodiment

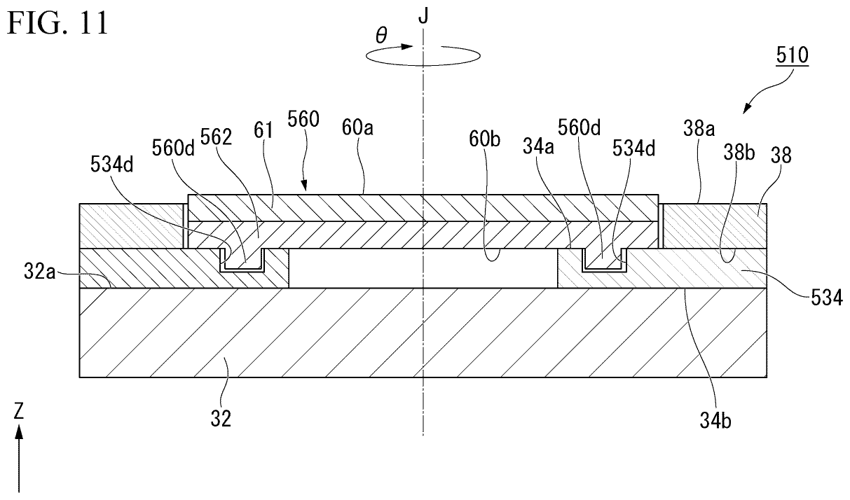

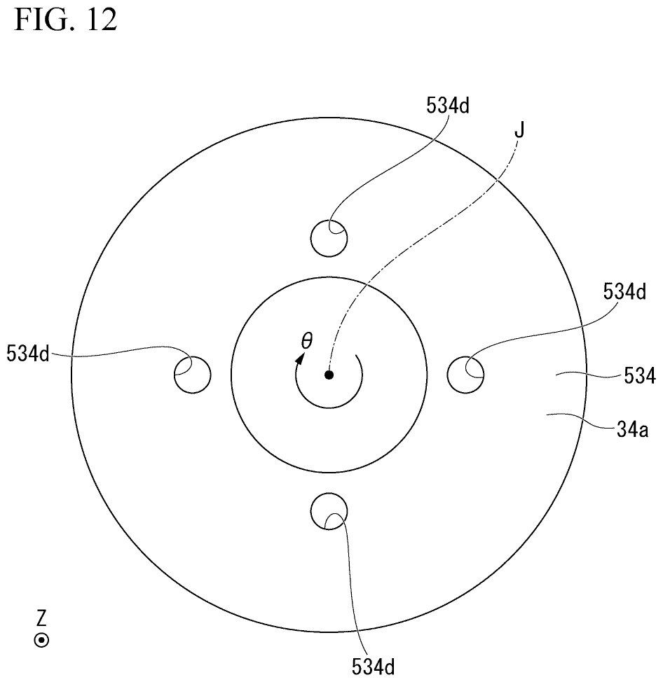

FIG. 11 is a cross-sectional view showing a part of a vapor phase growth apparatus 510 of the present embodiment. FIG. 12 is a plan view of a susceptor 534 of the present embodiment viewed from above. In the following description, the same reference signs are applied to constituent elements having the same forms as those in the embodiments described above, and a description thereof may be omitted.

A wafer 560 is mounted on the susceptor 534. The susceptor 534 supports each of the wafer 560 and the cover member 38 from below. The support surface 34a of the susceptor 534 supports the rear surface 60b of the wafer 560 from below. In the present embodiment, the support surface 34a is provided with a plurality of susceptor engagement portions 534d.

In the present embodiment, each of the susceptor engagement portions 534d is a depression depressed downward from the support surface 34a. As shown in FIG. 12, in the present embodiment, the support surface 34a is provided with four susceptor engagement portions 534d. The number of susceptor engagement portions 534d provided on the support surface 34a may be three or smaller or five or larger. Each of the plurality of susceptor engagement portions 534d has a circular shape in plan view. Each of the susceptor engagement portions 534d may have a different shape, such as a rectangular shape, a polygonal shape, and an elliptical shape in plan view. The susceptor engagement portions 534d are disposed with a gap therebetween in the circumferential direction. As shown in FIG. 11, at the time of deposition, a wafer engagement portion 560d provided in the wafer 560 (which will be described below) is accommodated in each of the susceptor engagement portions 534d. Other constitutions and the like of the susceptor 534 of the present embodiment are similar to other constitutions and the like of the susceptor 34 of the first embodiment described above.

The wafer 560 substantially has a disk shape extending in a direction orthogonal to the vertical direction. At the time of deposition, the wafer 560 is mounted in a radially inward part on the support surface 34a of the susceptor 534. In the present embodiment, the wafer 560 has the first wafer 61, a second wafer 562, and a plurality of wafer engagement portions 560d.

The second wafer 562 substantially has a disk shape extending in a direction orthogonal to the vertical direction. The downward facing surface of the second wafer 562 is the rear surface 60b of the wafer 560. Each of the wafer engagement portions 560d is a projection protruding downward from the rear surface 60b. In the present embodiment, each of the wafer engagement portions 560d has a circular shape in plan view. Although illustration is omitted, the wafer 560 has four wafer engagement portions 560d. The wafer engagement portions 560d are disposed with a gap therebetween in the circumferential direction. At the time of deposition, the wafer engagement portions 560d are accommodated inside the respective susceptor engagement portions 534d different from each other. The inner circumferential surface of each of the susceptor engagement portions 534d faces the wafer engagement portion 560d with a slight gap therebetween. Accordingly, the wafer engagement portion 560d is engaged with each of the susceptor engagement portions 534d. Other constitutions and the like of the wafer 560 of the present embodiment are similar to other constitutions and the like of the wafer 60 of the first embodiment described above. Other constitutions and the like of the vapor phase growth apparatus 510 of the present embodiment are similar to other constitutions and the like of the vapor phase growth apparatus 10 of the first embodiment described above.

According to the present embodiment, the support surface 34a has one or more additional susceptor engagement portions 534d configured to be engaged with one or more wafer engagement portion of the wafer, and the susceptor engagement portion 534d and the one or more additional susceptor engagement portion 534d are disposed with gaps therebetween in the circumferential direction. Thus, when the susceptor 534 having the wafer 560 mounted thereon is rotated, if the wafer 560 tends to move radially outward with respect to the susceptor 534, at least one wafer engagement portion 560d is caught by the inner circumferential surface of the susceptor engagement portion 534d. Accordingly, a situation in which the wafer 560 moves radially outward with respect to the susceptor 534 can be favorably curbed. Therefore, a situation in which the wafer 560 falls off from the susceptor 534 can be favorably curbed.

According to the present embodiment, the susceptor engagement portion 534d and the one or more additional susceptor engagement portion 534d have a circular shape in plan view. Thus, since each of the susceptor engagement portions 534d has a simple shape, it is easy to curb increase in man-hours for work of molding each of the susceptor engagement portions 534d. Therefore, increase in man-hours for molding the susceptor 534 can be curbed.

In addition, in the present embodiment, as described above, the susceptor engagement portion 534d and the one or more additional susceptor engagement portion 534d have a circular shape in plan view. For this reason, when the susceptor 534 having the wafer 560 mounted thereon is rotated, if the wafer 560 tends to move in the circumferential direction with respect to the susceptor 534, at least one wafer engagement portion 560d is caught by a part on the inner circumferential surface of the susceptor engagement portion 534d directed in the circumferential direction. Accordingly, a situation in which the wafer 560 moves in the circumferential direction with respect to the susceptor 534 can be favorably curbed. Therefore, since the rotation speed of the wafer 560 can be made stable, the uniformity of the thickness of the film deposited on the front surface 60a of the wafer 560 can be improved.

In addition, in the present embodiment, as described above, since a situation in which the wafer 560 falls off from the susceptor 534 can be favorably curbed, similar to the first embodiment described above, the thickness Tg of the cover member 38 can be suitably set to a height at which decrease in flow rate of the material gas G in the radial outer edge of the wafer 560 can be curbed. For this reason, a situation in which the thickness of the film deposited in the radial outer edge of the wafer 560 becomes excessively thinner than the thickness of the film deposited in the radially central portion of the wafer 560 can be curbed. Therefore, the uniformity of the thickness of the film deposited on the front surface 60a of the wafer 560 can be more favorably improved.

### Sixth Embodiment

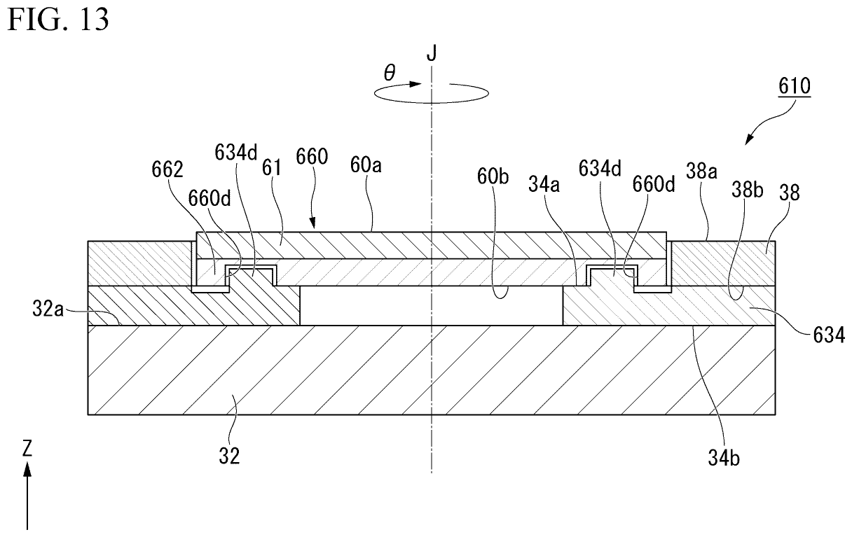

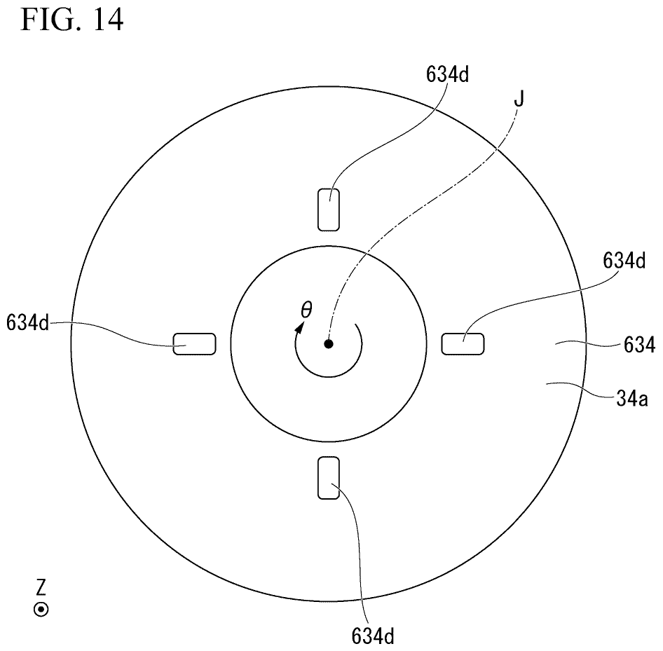

FIG. 13 is a cross-sectional view showing a part of the present embodiment a vapor phase growth apparatus 610. FIG. 14 is a plan view of a susceptor 634 of the present embodiment viewed from above. In the following description, the same reference signs are applied to constituent elements having the same forms as those in the embodiments described above, and a description thereof may be omitted.

A wafer 660 is mounted on the susceptor 634. The susceptor 634 supports each of the wafer 660 and the cover member 38 from below. The support surface 34a of the susceptor 634 supports the rear surface 60b of the wafer 660 from below. In the present embodiment, the support surface 34a is provided with a plurality of susceptor engagement portions 634d.

In the present embodiment, each of the susceptor engagement portions 634d is a projection protruding upward from the support surface 34a. As shown in FIG. 14, in the present embodiment, the support surface 34a is provided with four susceptor engagement portions 634d. The number of susceptor engagement portions 634d provided on the support surface 34a may be three or smaller or five or larger. Each of the plurality of susceptor engagement portions 634d has a rectangular shape in plan view. More specifically, each of the susceptor engagement portions 634d has a rectangular shape of which long sides extend in the radial direction in plan view. Each of the susceptor engagement portions 634d may have a different shape, such as a circular shape, a polygonal shape, an elliptical shape, and a rectangular shape of which long sides extend in the circumferential direction in plan view. The susceptor engagement portions 634d are disposed with a gap therebetween in the circumferential direction. As shown in FIG. 13, at the time of deposition, the susceptor engagement portions 634d are accommodated inside respective wafer engagement portions 660d which are different from each other and provided in the wafer 660 (which will be described below). Other constitutions and the like of the susceptor 634 of the present embodiment are similar to other constitutions and the like of the susceptor 34 of the first embodiment described above.

The wafer 660 substantially has a disk shape extending in a direction orthogonal to the vertical direction. At the time of deposition, the wafer 660 is mounted in a radially inward part on the support surface 34a of the susceptor 634. In the present embodiment, the wafer 660 has the first wafer 61, a second wafer 662, and a plurality of wafer engagement portions 660d.

The second wafer 662 substantially has a disk shape extending in a direction orthogonal to the vertical direction. The downward facing surface of the second wafer 662 is the rear surface 60b of the wafer 660. In the present embodiment, each of the wafer engagement portions 660d is a depression depressed upward from the rear surface 60b. In the present embodiment, each of the wafer engagement portions 660d has a rectangular shape of which long sides extend in the radial direction in plan view. Although illustration is omitted, the wafer 660 has four wafer engagement portions 660d. The wafer engagement portions 660d are disposed with a gap therebetween in the circumferential direction. At the time of deposition, the susceptor engagement portions 634d different from each other are accommodated inside the respective wafer engagement portions 660d. Each of the susceptor engagement portions 634d faces the inner circumferential surface of the wafer engagement portion 660d with a slight gap therebetween. Accordingly, each of the susceptor engagement portions 634d is engaged with the wafer engagement portion 660d. Each of the susceptor engagement portions 634d may come into contact with the inner circumferential surface of the wafer engagement portion 660d. Other constitutions and the like of the wafer 660 of the present embodiment are similar to other constitutions and the like of the wafer 60 of the first embodiment described above. Other constitutions and the like of the vapor phase growth apparatus 610 of the present embodiment are similar to other constitutions and the like of the vapor phase growth apparatus 10 of the first embodiment described above.

According to the present embodiment, the susceptor engagement portion 634d and the one or more additional susceptor engagement portion 634d have a rectangular shape in plan view. Thus, since each of the susceptor engagement portions 634d has a simple shape, it is easy to curb increase in man-hours for work of molding each of the susceptor engagement portions 634d. Therefore, increase in man-hours for molding the susceptor 634 can be curbed.

In addition, in the present embodiment, the susceptor 634 has the support surface 34a configured to support the rear surface 60b of the wafer 660, that is, the downward facing surface from below, and the support surface 34a has the susceptor engagement portions 634d configured to be engaged with the wafer engagement portions 660d of the wafer 660. Thus, similar to the first embodiment described above, at the time of deposition, a situation in which the wafer 660 falls off from the susceptor 634 can be curbed. Therefore, the thickness Tg of the cover member 38 can be suitably set to a height at which decrease in flow rate of the material gas G in the radial outer edge of the wafer 660 can be curbed. For this reason, similar to the first embodiment described above, a situation in which the thickness of the film deposited in the radial outer edge of the wafer 660 becomes excessively thinner than the thickness of the film deposited in the radially central portion of the wafer 660 can be curbed. Therefore, the uniformity of the thickness of the film deposited on the front surface 60a of the wafer 660 can be improved.

According to the susceptor and the vapor phase growth apparatus of the embodiment described above, the support surface configured to support the downward facing surface of the wafer from below has the susceptor engagement portion configured to be engaged with the wafer engagement portion of the wafer. Accordingly, the uniformity of the thickness of the film deposited on the front surface of the wafer can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A susceptor in a vapor phase growth apparatus and configured to allow a wafer to be mounted thereon, the susceptor comprising:
a support surface configured to support a downward facing surface of the wafer from below,
wherein the support surface has a susceptor engagement portion configured to be engaged with a wafer engagement portion of the wafer.

2. The susceptor according to claim 1,
wherein the susceptor engagement portion is a depression depressed downward from the support surface and accommodating the wafer engagement portion.

3. The susceptor according to claim 1,
wherein the susceptor engagement portion is a projection protruding upward from the support surface and accommodated inside the wafer engagement portion.

4. The susceptor according to claim 1,
wherein the susceptor engagement portion has a toric shape in plan view.

5. The susceptor according to claim 1,
wherein the support surface has one or more additional susceptor engagement portion configured to be engaged with one or more wafer engagement portion of the wafer, and
the susceptor engagement portion and the one or more additional susceptor engagement portion are disposed with gaps therebetween in a circumferential direction.

6. The susceptor according to claim 5,
wherein the susceptor engagement portion and the one or more additional susceptor engagement portion have a circular shape in plan view.

7. The susceptor according to claim 5,
wherein the susceptor engagement portion and the one or more additional susceptor engagement portion have a rectangular shape in plan view.

8. A vapor phase growth apparatus comprising:
the susceptor according to claim 1; and
a drive unit configured to rotate the susceptor.
